(19) United States
(12) Patent Application Publication
(10) Pub. No.: US 2015/0123715 A1
(43) Pub. Date: May 7, 2015

(54) POWER SEMICONDUCTOR CIRCUIT

(71) Applicant: Semikron Elektronik GmbH & Co., KG, Nurnberg (DE)

(72) Inventors: Sven BÜTOW, Nurnberg (DE); Rainer WEISS, Erlangen (DE)

(21) Appl. No.: 14/535,546

(22) Filed: Nov. 7, 2014

(30) Foreign Application Priority Data
Nov. 7, 2013 (DE) 10 2013 112 261.2

(51) Int. Cl. H02M 1/08; H03K 17/56; H03K 3/011

(52) U.S. Cl. CPC H02M 1/08; H03K 3/011; H03K 17/56; H02M 2001/0054
USPC 327/109

(57) ABSTRACT

A power semiconductor circuit comprising a power semiconductor switch having a control terminal and a first and a second load current terminal, and comprising a drive circuit. The power semiconductor circuit further comprises at least one of three further elements:

a temperature-dependent control terminal resistance element which is electrically connected between the drive circuit and the control terminal; and/or a temperature-dependent load current terminal resistance element which is electrically connected between the drive circuit and the second load current terminal; and/or a first current branch which electrically connects the control terminal is to the second load current terminal, wherein a temperature-dependent control load current terminal resistance element is electrically connected into the first current branch. In the event of heating of a power semiconductor switch, the invention reduces the switching losses of the power semiconductor switch.

### BACKGROUND OF THE INVENTION

1. Field of the Invention

The invention relates to power semiconductor circuits.

2. Description of the Related Art

In known power semiconductor devices, generally power semiconductor components such as, for example, power semiconductor switches and diodes, are arranged on a substrate and are electrically conductively connected to one another by a conductor layer of the substrate, and by bonding wires and/or a foil composite. In such devices, the power semiconductor switches are generally present in the form of transistors, such as, e.g., IGBTs (Insulated Gate Bipolar Transistor) or MOSFETs (Metal Oxide Semiconductor Field Effect Transistor).

In these known devices, the power semiconductor components arranged on the substrate are often electrically interconnected to form one or more so-called half-bridge circuits, which are used, e.g., for rectifying and inverting electrical voltages and currents.

Owing to, for example, parasitic inductances of leads to the power semiconductor switches, voltage spikes occur between the first and second load current terminals of the power semiconductor switches when the power semiconductor switches are switched off, and such voltage spikes, if they become too high, can damage or destroy the power semiconductor switches. The more slowly the power semiconductor switches are switched off, the lower the spikes and, therefore, the danger associated with the spikes. However, the more slowly the power semiconductor switches are switched off, the greater the energetic switching losses become which arise at the power semiconductor switches. This lowers the efficiency of the electrical circuits (e.g., half-bridge circuits) realized by the power semiconductor switches. On account of physical conditions, power semiconductor switches, in the event of increasing heating of the power semiconductor switches, switch off more slowly than when cold, which on the one hand does reduce the voltage spikes occurring when the power semiconductor switches are switched off, but on the other hand increases the energetic losses at the power semiconductor switches, thus resulting in a deterioration in the efficiency of the electrical circuits realized by means of the power semiconductor switches.

German Patent No. DE 103 61 714 A1 discloses an electrical resistance element which is connected between the control terminal and the second load current terminal of a power semiconductor switch and which has a negative temperature coefficient.

### SUMMARY OF THE INVENTION

The object of the invention is to provide an improved power semiconductor switch which demonstrates reduced switching losses when heated.

This object is achieved by a power semiconductor circuit which comprises a power semiconductor switch having a control terminal and first and second load current terminals. The inventive power semiconductor circuit further comprises a drive circuit for driving the power semiconductor switch, the drive circuit being electrically connected to the control terminal and to the second load current terminal.

The inventive power semiconductor circuit further comprises one or more of the following three elements:
a control terminal resistance element which is electrically connected between the drive circuit and the control terminal, and is thermally coupled to the power semiconductor switch, wherein the ohmic resistance of the control terminal resistance element at temperatures of the control terminal resistance element of about 175° C. and about 300° C. is a maximum of 90% of the ohmic resistance of the control terminal resistance element at a temperature of about 20° C.;
a load current terminal resistance element is electrically connected between the drive circuit and the second load current terminal, and is thermally coupled to the power semiconductor switch, wherein the ohmic resistance of the load current terminal resistance element at temperatures of about 175° C. and about 300° C. is a maximum of 90% of the ohmic resistance of the load current terminal resistance element at a temperature of about 20° C.; and/or
a first current branch which electrically connects the control terminal to the second load current terminal, and a control load current terminal resistance element which is electrically connected into the first current branch, wherein the control load current terminal resistance element is thermally coupled to the power semiconductor switch, and wherein the ohmic resistance of the control load current terminal resistance element at temperatures of about 175° C. and about 300° C. is at least about 150% of the ohmic resistance of the control load current terminal resistance element at a temperature of about 20° C.

In embodiments in which the power semiconductor circuit has the control terminal resistance element, it is preferred that the ohmic resistance of the control terminal resistance element at a temperatures of about 175° C. and about 300° C. is preferably no more than about 75% of the ohmic resistance of the control terminal resistance element at a temperature of about 20° C., and, even more preferably, no more than about 60% thereof.

In embodiments in which the power semiconductor circuit has the load current terminal resistance element, it is preferred that the ohmic resistance of the load current terminal resistance element at temperatures of the load current terminal resistance element of about 175° C. and about 300° C. is no more than about 75% of the ohmic resistance of the load current terminal resistance element at a temperature of about 20° C. and, even more preferably, no more than about 60% thereof.

Furthermore, In embodiments in which the power semiconductor circuit has the control load current terminal resistance element, it is preferred that the ohmic resistance of the control load current terminal resistance element at temperatures of about 175° C. and about 300° C. is preferably no more than about 200% of the ohmic resistance of the control load current terminal resistance element at a temperature of about 20° C. and, even more preferably, no less than about 500% thereof.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1 shows a power semiconductor device according to the invention;

FIG. 2 shows a power semiconductor circuit according to the invention;

FIG. 3 shows a further embodiment of a power semiconductor circuit according to the invention;

FIG. 4 shows a further embodiment of a power semiconductor circuit according to the invention;

FIG. 5 shows different embodiments of a thermal coupling to a power semiconductor switch in schematic sectional view; and

FIG. 6 shows a further embodiment of a power semiconductor circuit according to the invention.

### DETAILED DESCRIPTION OF THE PRESENTLY PREFERRED EMBODIMENTS

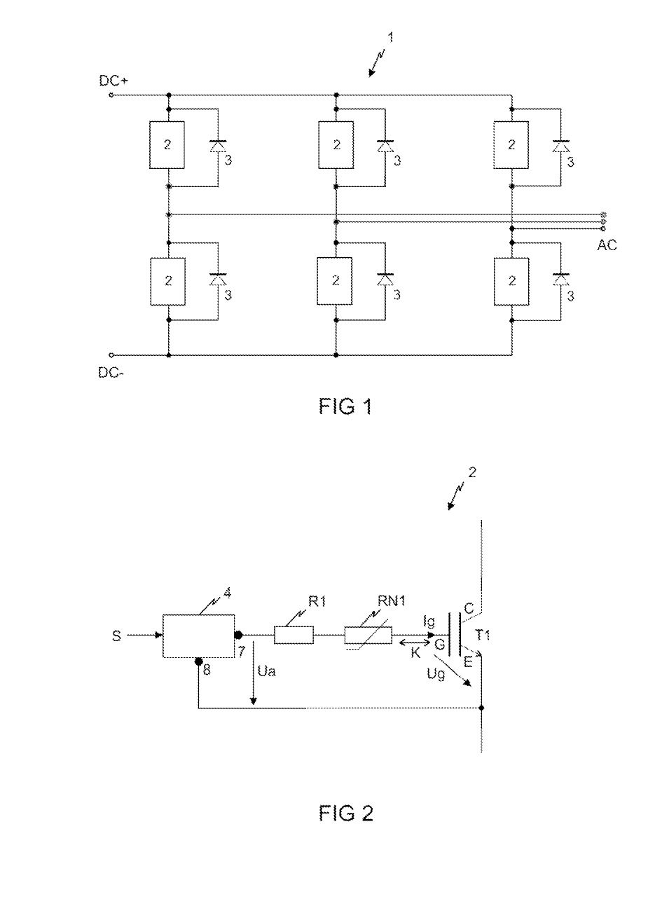

FIG. 1 shows a power semiconductor device 1 embodied by way of example in the form of a so-called three-phase bridge circuit. In the context of the exemplary embodiment, power semiconductor device 1 has six power semiconductor circuits 2 according to the invention. FIG. 2 illustrates a single power semiconductor circuit 2 according to the invention in detail. In the exemplary embodiment, a respective freewheeling diode 3 is electrically connected in antiparallel with power semiconductor circuits 2, wherein it is also possible for a plurality of freewheeling diodes to be electrically connected in antiparallel with each power semiconductor circuit 2. In the context of the exemplary embodiment illustrated, power semiconductor device 1 generates a three-phase AC voltage at the AC voltage terminal AC from a DC voltage fed in on the left side between the DC voltage terminals DC+ and DC−.

Each power semiconductor circuit 2 has a power semiconductor switch T1 has a first load current terminal C, a second load current terminal E and a control terminal G. In the context of the exemplary embodiment, first load current terminal C is present in the form of the collector of power semiconductor switch T1 and second load current terminal E is present in the form of the emitter of power semiconductor switch T1 and control terminal G is present in the form of the gate of power semiconductor switch T1. The power semiconductor switch is preferably present in the form of a transistor, such as, e.g., an IGBT (Insulated Gate Bipolar Transistor) or a MOSFET (Metal Oxide Semiconductor Field Effect Transistor), wherein power semiconductor switch T1 is present in the form of an n-channel IGBT in the context of the exemplary embodiment.

Furthermore, power semiconductor circuit 2 has a drive circuit 4, which is designed for driving power semiconductor switch T1, wherein drive circuit 4 is electrically connected to control terminal G of power semiconductor switch T1 and to second load current terminal E of power semiconductor switch T1. Drive circuit 4 can have one or more integrated circuits, and/or a plurality of discrete electrical components.

Drive circuit 4 generates a drive signal for driving power semiconductor switch T1 by generating a positive or negative output voltage Ua at its terminal 7 relative to its terminal 8. If power semiconductor switch T1 is to be switched on, output voltage Ua is positive. If power semiconductor switch T1 is to be switched off, output voltage Ua is negative. In the context of the exemplary embodiment, the drive signal generated by drive circuit 4 is dependent on a control signal S generated by an external control device (not shown).

A control terminal resistance element RN1 is electrically connected between drive circuit 4 and control terminal G. Control terminal resistance element RN1 is thermally coupled to power semiconductor switch T1, such that if power semiconductor switch T1 heats up, control terminal resistance element RN1 is heated. Control terminal resistance element RN1 is thermally conductively connected to power semiconductor switch T1. In FIG. 2, the thermal coupling of control terminal resistance element RN1 to power semiconductor switch T1 is represented by a double-headed arrow K. Control terminal resistance element RN1 is embodied as an NTC thermistor (Negative Temperature Coefficient), that is to say that the ohmic resistance of the control terminal resistance element decreases as the temperature increases, at least in a specific temperature range. Control terminal resistance element RN1 has a negative temperature coefficient at least in a specific temperature range. According to the invention, the ohmic resistance of control terminal resistance element RN1 at a temperature of either about 175° C. or about 300° C. is a maximum of 90%, preferably a maximum of 75%, more preferably a maximum of 60%, of the ohmic resistance of control terminal resistance element RN1 at a temperature of about 20° C. In the temperature range of 20° C. to 175° C. or to 300° C., the ohmic resistance preferably decreases monotonically, more preferably, strictly monotonically, as the temperature rises.

In the exemplary embodiment, control terminal resistance element RN1 has an ohmic resistance of 10Ω at 20° C. and of a maximum of 9Ω at either 175° C. or 300° C.

On account of physical conditions, a power semiconductor switch, in the event of increasing heating of the power semiconductor switch, switches off more slowly than in the cold state (e.g., at 20° C.). However, the speed at which power semiconductor switch T1 switches off is also dependent on the speed at which the control terminal voltage Ug for switching off power semiconductor switch T1 decreases, control terminal voltage Ug being present between control terminal G and second load current terminal E and relative to second load current terminal E. The faster control terminal voltage Ug decreases, the faster power semiconductor switch T1 switches off, that is to say the higher the switch-off speed at which power semiconductor switch T1 switches off and interrupts the load current flowing between the first and second load current terminals C and E. In the event of increasing heating of power semiconductor switch T1, the temperature of control terminal resistance element RN1 rises owing to the thermal coupling of control terminal resistance element RN1 to power semiconductor switch T1, which results in a reduction of the ohmic resistance of control terminal resistance element RN1. The reduction of the ohmic resistance of control terminal resistance element RN1 brings about an increase in the control current Ig in the negative direction if, instead of the positive output voltage Ua, a negative output voltage Ua is generated by drive circuit 4 for switching off power semiconductor switch T1. Owing to that, control terminal voltage Ug decreases faster than in the case of an unreduced ohmic resistance of control terminal resistance element RN1, which brings about an increase in the switch-off speed at which power semiconductor switch T1 is switched off. The increase in the switch-off speed at which power semiconductor switch T1 is switched off, owing to the reduction of the ohmic resistance of control terminal resistance element RN1, counteracts the reduction of the switch-off speed on account of the heating of power semiconductor switch T1. The occurrence of an increase in the switching losses of power semiconductor switch T1 on account of an increase in the temperature of power semiconductor switch T1 is at least reduced or even avoided as a result.

Preferably, an additional ohmic resistance element R1 is connected between drive circuit 4 and power semiconductor switch T1. Ohmic resistance element R1 can be embodied, e.g., in the form of a carbon film or metal film resistor conventional in the art. The electrical resistance of ohmic resistance element R1 is preferably temperature-dependent only to a relatively small extent, this dependence preferably being in the conventional range of carbon film or metal film resistors in the art. Ohmic resistance element R1 can be electrically connected in series with control terminal resistance element RN1, between drive circuit 4 and control terminal G of power semiconductor switch T1, or between drive circuit 4 and second load current terminal E of power semiconductor switch T1. Ohmic resistance element R1 ensures that, independently of the temperature of power semiconductor switch T1, a specific minimum ohmic resistance is electrically connected between drive circuit 4 and power semiconductor switch T1. In the exemplary embodiment, the electrical resistance of the ohmic resistance element R1 is 1Ω.

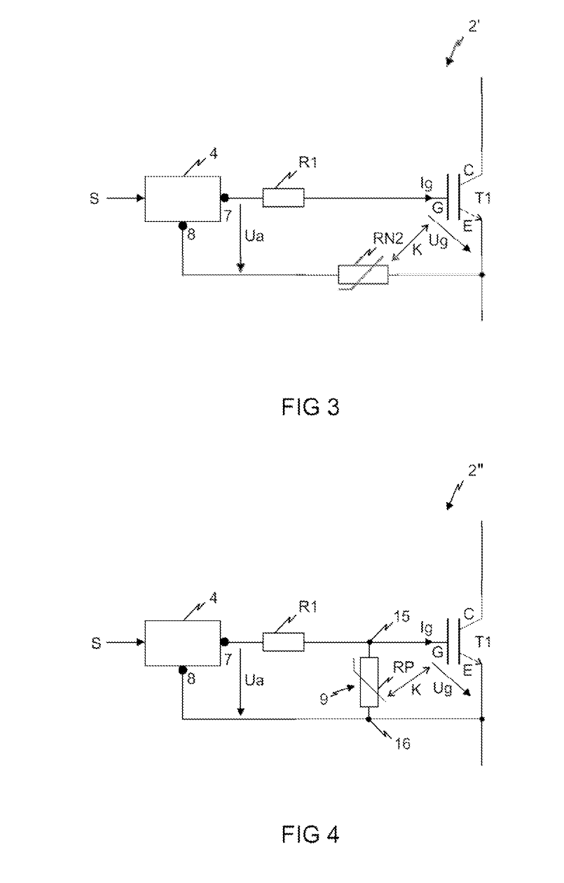

FIG. 3 illustrates a further embodiment of a power semiconductor circuit 2′ according to the invention in detail. In this case, power semiconductor circuit 2′ in accordance with FIG. 3 corresponds to the power semiconductor circuit 2 shown in FIG. 2 apart from the feature that, instead of control terminal resistance element RN1, power semiconductor circuit 2′ in FIG. 3 has a load current terminal resistance element RN2, which is electrically connected between drive circuit 4 and second load current terminal E of power semiconductor switch T1. In this case, load current terminal resistance element RN2 is embodied identically to control terminal resistance element RN1, such that, with regard to the description of the load current terminal resistance element RN2, reference is made to the above description of control terminal resistance element RN1. Load current terminal resistance element RN2 is thermally coupled to power semiconductor switch T1, which is represented by a double-headed arrow K. In the exemplary embodiment, load current terminal resistance element RN2 has an ohmic resistance of 10Ω at 20° C. and of a maximum of 9Ω at 175° C. or 300° C. The functional principle of the circuit in accordance with FIG. 3 corresponds to the functional principle described with respect to the exemplary embodiment in accordance with FIG. 2.

Preferably, an additional ohmic resistance element R1 is connected between drive circuit 4 and power semiconductor switch T1. Ohmic resistance element R1 can be embodied, e.g., in the form of a carbon film or metal film resistor conventional in the art. The electrical resistance of ohmic resistance element R1 is preferably temperature-dependent only to a relatively small extent, this dependence preferably being in the conventional range of carbon film or metal film resistors in the art. Ohmic resistance element R1 can be connected between drive circuit 4 and control terminal G of power semiconductor switch T1 or can be electrically connected in series with load current terminal resistance element RN2 between drive circuit 4 and the second load current terminal of power semiconductor switch T1. Ohmic resistance element R1 ensures that, independently of the temperature of power semiconductor switch T1, a specific minimum ohmic resistance is electrically connected between drive circuit 4 and power semiconductor switch T1. In the exemplary embodiment, the electrical resistance of ohmic resistance element R1 is 1Ω.

Control terminal resistance element RN1 and load current terminal resistance element RN2 consist of specially doped semiconductor materials such as silicon, for example, or of metal oxides of manganese, nickel, iron, cobalt, titanium or copper, for example, as is conventional in the art.

FIG. 4 illustrates a further embodiment of a power semiconductor circuit 2″ according to the invention in detail. In this case, power semiconductor circuit 2″ in accordance with FIG. 4 corresponds to power semiconductor circuit 2 in accordance with FIG. 2 apart from the features that, in the case of power semiconductor circuit 2″ in accordance with FIG. 4, control terminal G is electrically connected to second load current terminal E via a first current branch 9, wherein a control load current terminal resistance element RP is electrically connected into first current branch 9, wherein control load current terminal resistance element RP is thermally coupled to power semiconductor switch T1, wherein the ohmic resistance of control load current terminal resistance element RP at a temperature of the control load current terminal resistance element RP of either 175° C. or 300° C. is a minimum of 150%, preferably a minimum of 200%, more preferably a minimum of 500%, of the ohmic resistance of control load current terminal resistance element RP at a temperature of the control load current terminal resistance element RP of 20° C. In the context of the exemplary embodiment, current branch 9 is electrically connected in parallel with control terminal G and second load current terminal E of power semiconductor switch T1. In the exemplary embodiment, the first terminal 15 of control load current terminal resistance element RP is electrically conductively connected to control terminal G and the second terminal 16 of control load current terminal resistance element RP is electrically conductively connected to second load current terminal E of power semiconductor switch T1.

Control load current terminal resistance element RP is thermally coupled to power semiconductor switch T1, such that if power semiconductor switch T1 heats up, control load current terminal resistance element RP is heated. Control load current terminal resistance element RP is thermally conductively connected to power semiconductor switch T1. In FIG. 4, the thermal coupling of control load current terminal resistance element RP to power semiconductor switch T1 is represented by a double-headed arrow K. Control load current terminal resistance element RP is embodied as a PTC thermistor (Positive Temperature Coefficient), i.e., the ohmic resistance of control load current terminal resistance element RP increases as the temperature increases, at least in a specific temperature range. Control load current terminal resistance element RP has a positive temperature coefficient at least in a specific temperature range. In the temperature range of about 20° C. to about 175° C. or to about 300° C., the ohmic resistance preferably increases monotonically, more preferably strictly monotonically, as the temperature rises.

In the exemplary embodiment, the control load current terminal resistance element RP has an ohmic resistance of 100Ω at 20° C. and of a minimum of 150Ω at 175° C. or 300° C.

In the event of increasing heating of power semiconductor switch T1, owing to the thermal coupling of control load current terminal resistance element RP to power semiconductor switch T1, the temperature of control load current terminal resistance element RP rises, which results in an increase in the ohmic resistance of control load current terminal resistance element RP. The increase in the ohmic resistance of control load current terminal resistance element RP brings about an increase in the control current Ig in the negative direction if, instead of the positive output voltage Ua, a negative output voltage Ua is generated by drive circuit 4 for switching off power semiconductor switch T1. Owing to that, the control terminal voltage Ug decreases faster than in the case of a non-increased ohmic resistance of the control load current terminal resistance element RP, which brings about an increase in the switch-off speed at which power semiconductor switch T1 is switched off.

Preferably, an ohmic resistance element R1 is electrically connected between drive circuit 4 and control load current terminal resistance element RP. Ohmic resistance element R1 can be embodied, e.g., in the form of a conventional carbon film or metal film resistor known in the art. The electrical resistance of ohmic resistance element R1 is preferably temperature-dependent to a small extent, this dependence preferably being in the conventional range of carbon film or metal film resistors known in the art. Ohmic resistance element R1 can be electrically connected between drive circuit 4 and first terminal 15 of control load current terminal resistance element RP or between drive circuit 4 and second terminal 16 of control load current terminal resistance element RP. If drive circuit 4 internally has an ohmic internal resistance of corresponding magnitude which brings about a decrease in the negative output voltage Ua, if at a temperature of 20° C. the ohmic resistance of control load current terminal resistance element RP is low and drive circuit 4 is thus loaded with the current flowing through control load current terminal resistance element RP to a greater extent than at a higher temperature of control load current terminal resistance element RP, then ohmic resistance element R1 can also be omitted.

In the exemplary embodiment, the electrical resistance of ohmic resistance element R1 is 10Ω.

Control load current terminal resistance element RP preferably consists of specially doped silicon or barium titanate, for example in a manner conventional in the art.

FIG. 5 illustrates by way of example different embodiments of a thermal coupling of control terminal resistance element RN1, of load current terminal resistance element RN2 or of control load current terminal resistance element RP to power semiconductor switch T1 in the form of a schematic sectional view. Power semiconductor switch T1 is arranged on a substrate 13. Substrate 13 is preferably arranged on a heat sink 14. Substrate 13 is preferably embodied as a direct copper bonded substrate (DCB substrate) or as an insulated metal substrate (IMS). Control terminal resistance element RN1, load current terminal resistance element RN2 or control load current terminal resistance element RP can be, e.g., thermally coupled to power semiconductor switch T1 by virtue of control terminal resistance element RN1, load current terminal resistance element RN2 or control load current terminal resistance element RP being arranged on substrate 13 or on power semiconductor switch T1 or being monolithically integrated in power semiconductor switch T1.

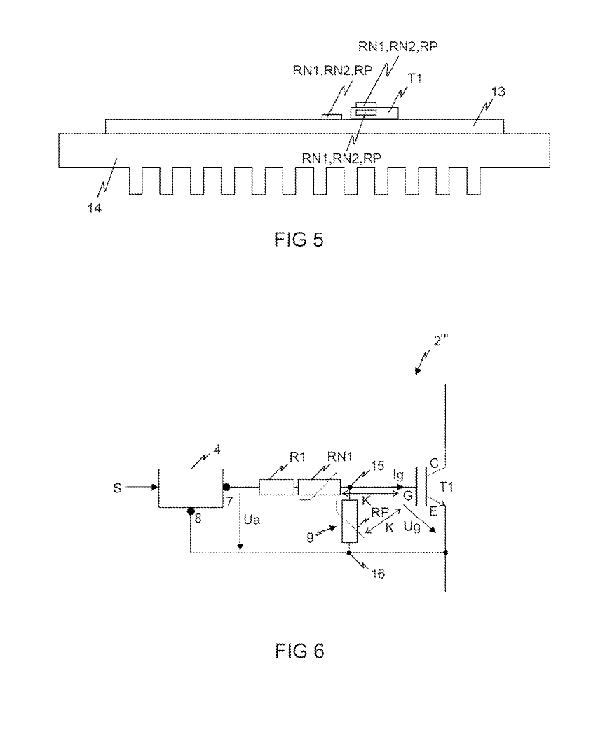

It should be noted at this juncture that the embodiments of the invention as indicated in FIGS. 2 to 4 or individual features of the embodiments of the invention or individual features of advantageous embodiments of the invention can be combined with one another arbitrarily. In this regard, by way of example, power semiconductor circuit 2 can have both control terminal resistance element RN1 and load current terminal resistance element RN2, or have both the control load current terminal resistance element RP and control terminal resistance element RN1 and/or load current terminal resistance element RN2. FIG. 6 indicates by way of example an embodiment of the invention in which the embodiments of the inventions in accordance with FIG. 2 and FIG. 4 are combined with one another.

It should be noted at this juncture that power semiconductor circuit 2 can have even further power semiconductor switches, which are generally electrically connected in parallel or in series with power semiconductor switch T1, wherein the control terminals and second load current terminals of the further power semiconductor switches are electrically connected to the drive circuit in a manner analogous to that described above and the further power semiconductor switches are driven by the drive circuit in a manner analogous to that described above.

Furthermore, it should be noted that the functioning of the invention as described with regard to switching off the power semiconductor switch, as regards the switching losses, analogously also applies to switching on the power semiconductor switch, such that an increase in the switching losses of power semiconductor switch T1 that occurs when the power semiconductor switch is switched on, on account of an increase in the temperature of power semiconductor switch T1, is also at least reduced or even avoided by means of the invention.

It should also be noted that in a conventional manner in the art often for switching on and for switching off the power semiconductor switch the drive circuit can be connected to the power semiconductor switch via a current branch respectively responsible for the switching on and the switching off, wherein different ohmic gate series resistors are connected in the respective current branch. Correspondingly, a control terminal resistance element, load current terminal resistance element and/or a control load current terminal resistance element or an ohmic resistance element for switching off the power semiconductor switch and a further control terminal resistance element, further load current terminal resistance element and/or a further control load current terminal resistance element or a further ohmic resistance element for switching on the power semiconductor switch can also be present.

In the preceding Detailed Description, reference was made to the accompanying drawings, which form a part of his disclosure, and in which are shown illustrative specific embodiments of the invention. In this regard, directional terminology, such as “top”, “bottom”, “left”, “right”, “front”, “back”, etc., is used with reference to the orientation of the Figure(s) with which such terms are used. Because components of embodiments can be positioned in a number of different orientations, the directional terminology is used for purposes of ease of understanding and illustration only and is not to be considered limiting.

Additionally, while there have been shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A power semiconductor circuit comprising:
a power semiconductor switch having a control terminal and first and second load current terminals;
a drive circuit electrically connected to said control terminal and to said second load current terminal for driving said power semiconductor switch; and
a control terminal resistance element electrically connected between said drive circuit and said control terminal;
wherein said control terminal resistance element is thermally coupled to said power semiconductor switch; and
wherein an ohmic resistance of said control terminal resistance element at a temperature of at least one of about 175° C. and about 300° C. is no more than about 90% of an ohmic resistance of said control terminal resistance element at a temperature of about 20° C.

2. The power semiconductor circuit of claim 1, wherein said ohmic resistance of said control terminal resistance element at a temperature of at least one of about 175° C. and about 300° C. is no more than about 75% of said ohmic resistance of said control terminal resistance element at a temperature of about 20° C.

3. The power semiconductor circuit of claim 2, wherein said ohmic resistance of said control terminal resistance element at a temperature of at least one of about 175° C. and about 300° C. is no more than about 60% of said ohmic resistance of said control terminal resistance element at a temperature of about 20° C.

4. The power semiconductor circuit of claim 1, further comprising a load current terminal resistance element electrically connected between said drive circuit and said second load current terminal;
wherein said load current terminal resistance element is thermally coupled to said power semiconductor switch; and
wherein an ohmic resistance of said load current terminal resistance element at a temperature of at least one of about 175° C. and about 300° C. is no more than about 90% of said ohmic resistance of said load current terminal resistance element at a temperature of about 20° C.

5. The power semiconductor circuit of claim 4, wherein said ohmic resistance of said load current terminal resistance element at a temperature of at least one of about 175° C. and about 300° C. is no more than about 75% of said ohmic resistance of said load current terminal resistance element at a temperature of about 20° C.

6. The power semiconductor circuit of claim 5, wherein said ohmic resistance of said load current terminal resistance element at a temperature of at least one of about 175° C. and about 300° C. is no more than about 60% of said ohmic resistance of said load current terminal resistance element at a temperature of about 20° C.

7. The power semiconductor circuit of claim 4, further comprising:
a first current branch which electrically connects said control terminal to said second load current terminal; and
a control load current terminal resistance element electrically connected into said first current branch;
wherein said control load current terminal resistance element is thermally coupled to said power semiconductor switch; and
wherein an ohmic resistance of said control load current terminal resistance element at a temperature of at least one of about 175° C. and about 300° C. is no less than about 150% of said ohmic resistance of said control load current terminal resistance element at a temperature of about 20° C.

8. The power semiconductor circuit of claim 7, wherein said ohmic resistance of said control load current terminal resistance element at a temperature of at least one of about 175° C. and about 300° C. is no less than about 200% of said ohmic resistance of said control load current terminal resistance element at a temperature of about 20° C.

9. The power semiconductor circuit of claim 7, wherein said ohmic resistance of said control load current terminal resistance element at a temperature of at least one of about 175° C. and about 300° C. is no less than about 500% of said ohmic resistance of said control load current terminal resistance element at a temperature of about 20° C.

10. A power semiconductor circuit comprising:
a power semiconductor switch having a control terminal and first and second load current terminals;
a drive circuit electrically connected to said control terminal and to said second load current terminal for driving said power semiconductor switch; and
a load current terminal resistance element electrically connected between said drive circuit and said second load current terminal;
wherein said load current terminal resistance element is thermally coupled to said power semiconductor switch; and
wherein an ohmic resistance of said load current terminal resistance element at a temperature of at least one of about 175° C. and about 300° C. is no more than about 90% of said ohmic resistance of said load current terminal resistance element at a temperature of about 20° C.

11. The power semiconductor circuit of claim 10, further comprising a load current terminal resistance element electrically connected between said drive circuit and said second load current terminal;
wherein said load current terminal resistance element is thermally coupled to said power semiconductor switch; and
wherein an ohmic resistance of said load current terminal resistance element at a temperature of at least one of about 175° C. and about 300° C. is no more than about 90% of said ohmic resistance of said load current terminal resistance element at a temperature of about 20° C.

12. The power semiconductor circuit of claim 11, wherein an ohmic resistance of said load current terminal resistance element at a temperature of at least one of about 175° C. and about 300° C. is no more than about 75% of said ohmic resistance of said load current terminal resistance element at a temperature of about 20° C.

13. The power semiconductor circuit of claim 12, wherein ohmic resistance of said load current terminal resistance element at a temperature of at least one of about 175° C. and about 300° C. is no more than about 60% of said ohmic resistance of said load current terminal resistance element at a temperature of about 20° C.

14. The power semiconductor circuit of claim 11, further comprising:
a first current branch which electrically connects said control terminal to said second load current terminal; and
a control load current terminal resistance element electrically connected into said first current branch;
wherein said control load current terminal resistance element is thermally coupled to said power semiconductor switch; and
wherein an ohmic resistance of said control load current terminal resistance element at a temperature of at least one of about 175° C. and about 300° C. is no less than about 150% of said ohmic resistance of said control load current terminal resistance element at a temperature of about 20° C.

15. The power semiconductor circuit of claim 14, wherein said ohmic resistance of said control load current terminal resistance element at a temperature of at least one of about 175° C. and about 300° C. is no less than about 200% of said ohmic resistance of said control load current terminal resistance element at a temperature of about 20° C.

16. The power semiconductor circuit of claim 15, wherein said ohmic resistance of said control load current terminal resistance element at a temperature of at least one of about 175° C. and about 300° C. is no less than about 500% of said ohmic resistance of said control load current terminal resistance element at a temperature of about 20° C.

17. A power semiconductor circuit comprising:
a power semiconductor switch having a control terminal and first and second load current terminals;
a drive circuit electrically connected to said control terminal and to said second load current terminal for driving said power semiconductor switch;
a first current branch which electrically connects said control terminal to said second load current terminal; and
a control load current terminal resistance element electrically connected into said first current branch;
wherein said control load current terminal resistance element is thermally coupled to said power semiconductor switch; and
wherein an ohmic resistance of said control load current terminal resistance element at a temperature of at least one of about 175° C. and about 300° C. is no less than about 150% of said ohmic resistance of said control load current terminal resistance element at a temperature of about 20° C.

18. The power semiconductor circuit of claim 17, wherein said ohmic resistance of said control load current terminal resistance element at a temperature of at least one of about 175° C. and about 300° C. is no less than about 200% of said ohmic resistance of said control load current terminal resistance element at a temperature of about 20° C.

19. The power semiconductor circuit of claim 18, wherein said ohmic resistance of said control load current terminal resistance element at a temperature of at least one of about 175° C. and about 300° C. is no less than about 500% of said ohmic resistance of said control load current terminal resistance element at a temperature of about 20° C.
